(19) United States
(12) Patent Application Publication
(10) Pub. No.: US 2026/0215091 A1
(43) Pub. Date: Jul. 23, 2026

(54) DISPLAY MODULE AND ELECTRONIC DEVICE INCLUDING THE SAME

(71) Applicant: Samsung Display Co., Ltd., Yongin-Si (KR)

(72) Inventors: Jinsu Byun, Yongin-si (KR); Yeongwoo Kwon, Yongin-si (KR); Yangho Jung, Yongin-si (KR); Gwangmin Cha, Yongin-si (KR)

(21) Appl. No.: 19/266,986

(22) Filed: Jul. 11, 2025

(30) Foreign Application Priority Data
Jan. 21, 2025 (KR) 10-2025-0008534

(51) Int. Cl. H10K 59/122; H10K 59/80

(52) U.S. Cl. CPC H10K 59/122; H10K 59/873

(57) ABSTRACT

Provided are a display module with improved light emission efficiency and an electronic device including the same, the display module including a substrate, a thin film transistor disposed on the substrate, an insulating layer disposed on the thin film transistor and including a protrusion, a pixel electrode disposed on the insulating layer and covering the protrusion, a pixel-defining layer on the pixel electrode, an intermediate layer on the pixel-defining layer, a first encapsulation layer having a portion protruding toward an upper portion to correspond to the protrusion on the intermediate layer, and a second encapsulation layer disposed on the first encapsulation layer and having a refractive index less than a refractive index of the first encapsulation layer.

### CROSS-REFERENCE TO RELATED APPLICATION

This application is based on and claims priority under 35 U.S.C. §119 to Korean Patent Application No. 10-2025-0008534, filed on January 21, 2025, in the Korean Intellectual Property Office, the disclosure of which is incorporated by reference herein in its entirety.

### BACKGROUND

### 1. Field

Aspects of the present disclosure relate to a display module and an electronic device including the display module, and more particularly, to a display module with improved light emission efficiency and an electronic device including the display module.

### 2. Description of the Related Art

A display module may receive information about an image and display the image. The display module may be used as a display portion of small products such as mobile phones, or as a display portion of large products such as televisions.

The display module includes a plurality of pixels that emit light in response to electrical signals to display images externally. Each pixel includes a light-emitting element, and for example, in the case of an organic light-emitting display device, an organic light-emitting diode may be included as the light-emitting element. Generally, the display module may include a thin film transistor and an organic light-emitting diode on a substrate.

In addition, an electronic device may provide a visual interface necessary for a user through the display module.

### SUMMARY

Aspects of the present disclosure include a display module with improved light emission efficiency and an electronic device including the display module. However, these objectives are provided as examples only, and the scope of the disclosure is not limited thereby.

Additional aspects will be set forth in part in the description which follows and, in part, will be apparent from the description, or may be learned by practice of the presented embodiments of the disclosure.

According to aspects of the present disclosure, a display module may include a substrate, a first thin film transistor disposed on the substrate, an insulating layer disposed on the first thin film transistor and having a first through-hole, the insulating layer including a first, first protrusion having a first height around the first through-hole, a first pixel electrode disposed on the insulating layer and electrically connected to the first thin film transistor through the first through-hole, the first pixel electrode having a step corresponding to the first height with reference to an upper surface of the insulating layer, a pixel-defining layer disposed on the first pixel electrode and exposing at least a central portion of the first pixel electrode toward an upper portion, a first intermediate layer disposed on the pixel-defining layer, generating light of a first wavelength, and covering at least the central portion of the first pixel electrode, a first encapsulation layer disposed on the first intermediate layer, having a first refractive index, and including a second, first protrusion protruding toward the upper portion, and a second encapsulation layer disposed on the first encapsulation layer and having a second refractive index that is less than the first refractive index.

In a plan view, the first, first protrusion may be disposed within the second. first protrusion.

In a plan view, the first through-hole and the first, first protrusion may be spaced apart.

In a plan view, the first pixel electrode may be disposed within the second, first protrusion.

In a plan view, at least the central portion of the first pixel electrode may be disposed within an upper surface of the second, first protrusion.

In a plan view, at least the central portion of the first pixel electrode may not overlap an outer side surface of the second, first protrusion.

A difference between the first refractive index and the second refractive index may be between 0.1 to 0.7 inclusive of endpoints.

A thickness of the first, first protrusion may be greater than a thickness of the pixel-defining layer.

The pixel-defining layer may include an inorganic material.

The first encapsulation layer may include an inorganic material, and the second encapsulation layer may include a monomer-based material.

The display module may further include a third encapsulation layer disposed on the second encapsulation layer, and the third encapsulation layer may include an inorganic material.

The second, first protrusion may be disposed in an optical path of light of the first wavelength proceeding from the first intermediate layer in a direction opposite to the substrate.

The outer side surface of the second, first protrusion may refract the light of the first wavelength.

The insulating layer may have a second through-hole and may include a first, second protrusion having a second height around the second through-hole.

The display module may further include a second thin film transistor disposed on the substrate, a second pixel electrode disposed on the same layer as the first pixel electrode, electrically connected to the second thin film transistor through the second through-hole, having a step corresponding to the second height with reference to the upper surface of the insulating layer, and having at least a central portion exposed toward the upper portion by the pixel-defining layer, and a second intermediate layer disposed on the same layer as the first intermediate layer, generating light of a second wavelength, and covering at least the central portion of the second pixel electrode.

The first wavelength may be smaller than the second wavelength, and the first height may be greater than the second height.

The first encapsulation layer may further include a second, second protrusion protruding toward the upper portion.

In a plan view, the first, second protrusion may be disposed within the second-2nd protrusion.

In a plan view, the second through-hole and the first, second protrusion may be spaced apart.

In a plan view, at least the central portion of the second pixel electrode may be disposed within an upper surface of the second, second protrusion.

In a plan view, at least the central portion of the second pixel electrode may not overlap with an outer side surface of the second, second protrusion.

According to one or more embodiments, an electronic device includes a memory configured to store data information, a processor configured to generate a data signal and/or a control signal based on the data information, and any one of the above-described display modules configured to operate based on the data signal and/or the control signal.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view illustrating a display module included in a display device according to aspects of the present disclosure

FIG. 2 is an example of a schematic equivalent circuit diagram of a subpixel of the display device of FIG. 1 according to aspects of the present disclosure;

FIG. 3 is an example of a schematic cross-sectional view showing a cross-section obtained from the display area of FIG. 1 according to aspects of the present disclosure;

FIG. 4 is an example of a schematic cross-sectional view showing a cross-section obtained from the display area of FIG. 1 according to aspects of the present disclosure;

FIG. 5 is an example of a schematic cross-sectional view showing a cross-section obtained from the display area of FIG. 1 according to aspects of the present disclosure;

FIG. 6 is an example of a schematic cross-sectional view showing a cross-section obtained from the display area of FIG. 1 according to aspects of the present disclosure;

FIG. 7 is a diagram showing (a) a graph representing light emission efficiency of a display module according to a comparative example and (b) a graph representing light emission efficiency of a display module according to FIG. 3 according to aspects of the present disclosure;

FIGS. 8 to 12 are diagrams sequentially showing a process of manufacturing the display module of FIG. 3 according to aspects of the present disclosure;

FIG. 13 is a cross-sectional view showing an example of a cross-section of a display module according to aspects of the present disclosure;

FIG. 14 is a block diagram of an electronic device according to aspects of the present disclosure; and

FIG. 15 is a schematic diagram of electronic devices according to aspects of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

The disclosure may be embodied in many different forms and should not be construed as being limited to the embodiments set forth herein. Rather, these embodiments are provided so that this disclosure will be thorough and complete, and will fully convey the scope of the disclosure to those skilled in the art. The effects and features of the disclosure and methods for achieving them will become more apparent from the following detailed description of the embodiments when taken in conjunction with the accompanying drawings. However, the disclosure is not limited to the embodiments disclosed below but may be implemented in various forms.

Hereinafter, embodiments of the disclosure will be described in detail with reference to the accompanying drawings, and when describing with reference to the drawings, the same or corresponding components may be denoted by the same reference numerals, and repetitive description thereof will be omitted.

In the following embodiments, the terms "first," "second," etc. are used for the purpose of distinguishing one component from another component, not in a limiting sense. Furthermore, in the following embodiments, a singular expression includes a plural expression unless the context clearly indicates otherwise.

In the following embodiments, when a layer, film, region, plate, or other component is described as being "on" another component, it includes not only the case where the component is "directly on" the other component, but also the case where another component is interposed therebetween.

Also, for convenience of explanation, the size of components may be exaggerated or reduced in the drawings. For example, the size and thickness of each component shown in the drawings are arbitrarily shown for convenience of explanation, and thus the disclosure is not necessarily limited to what is shown.

In the following embodiments, terms such as "include" or "have" indicate the presence of features or components described in the specification, and do not preclude the possibility of adding one or more other features or components.

In the following embodiments, when a portion of a film, region, component, etc. is described as being "on" another portion, it includes not only the case where the portion is directly on the other portion, but also the case where another film, region, component, etc. is interposed therebetween.

When an embodiment may be implemented differently, a specific process order may be performed differently from the described order. For example, two processes described sequentially may be performed substantially simultaneously or in the reverse order from the described sequence.

In this specification, "A and/or B" indicates a case where it is A, B, or both A and B. In addition, "at least one of A and B" indicates a case where it is A, B, or both A and B.

In the following embodiments, when a film, region, component, etc. is described as being "connected," it includes not only the case where the film, region, component, etc. is directly connected, but also the case where another film, region, component, etc. is interposed therebetween to be indirectly connected. For example, in this specification, when a film, region, component, etc. is described as being "electrically connected," it indicates a case where the film, region, component, etc. is directly electrically connected, and/or where another film, region, component, etc. is interposed therebetween to be indirectly electrically connected.

In the following embodiments, the x-axis, y-axis, and z-axis are not limited to three axes in an orthogonal coordinate system, but may be interpreted in a broader sense including orthogonal coordinate systems. For example, the x-axis, y-axis, and z-axis may be orthogonal to each other, or may refer to different directions that are not orthogonal to each other.

Hereinafter, based on the above contents, a display module according to according to an embodiment will be described in detail below

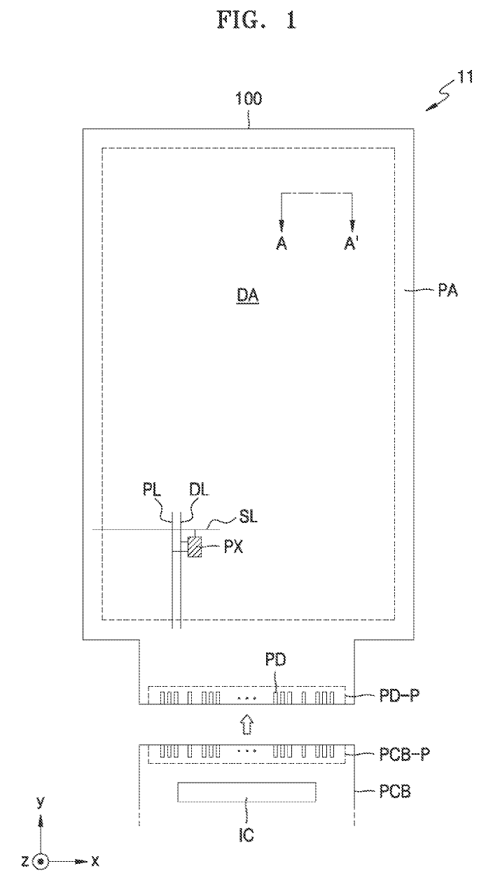

FIG. 1 is a schematic plan view illustrating a display module included in a display device according to aspects of the present disclosure.

As shown in FIG. 1, the display module 11 includes a display area DA and a peripheral area PA located outside the display area DA. In FIG. 1, the display area DA is shown as having a rectangular shape, but the disclosure is not limited to the rectangular shape. The display area DA may have various shapes such as, for example, circular, ellipse, polygonal, or specific geometric shapes.

The display area DA is a portion that may display an image, and a plurality of subpixels PX may be arranged therein. Each subpixel PX may include a display element such as an organic light-emitting diode. Each subpixel PX may emit, for example, red, green, or blue light. The subpixels PX may be connected to a pixel circuit including a thin film transistor TFT, a storage capacitor, etc. The pixel circuit may be connected to a scan line SL for transmitting a scan signal, a data line DL that crosses the scan line SL and transmits a data signal, and a driving voltage line PL for supplying a driving voltage. For example, the data line DL and the driving voltage line PL may extend in the y-axis direction (hereinafter, a first direction), and the scan line SL may extend in the x-axis direction (hereinafter, a second direction).

The subpixel PX may emit light with a luminance corresponding to an electrical signal received from the data line DL. The display area DA may display a predetermined image through light emitted from the subpixels PX. For example and without limitation, a subpixel PX may be defined as an emission area that emits one of red, green, and blue light.

The peripheral area PA is an area where subpixels PX are not arranged, and may be an area that does not display an image. In the peripheral area PA, power supply wiring for driving the subpixels PX may be arranged. Also, pads PD may be arranged in the peripheral area PA, and the peripheral area PA may include a pad area PD-P where the pads PD are arranged.

An integrated circuit device IC such as a driver Integrated Circuit may be mounted on a printed circuit board PCB including a driving circuit portion, and terminals electrically connected to the integrated circuit device IC may be arranged in a terminal area PCB-P of the printed circuit board(PCB. The terminal area PCB-P corresponds to the pad area PD-P, and the aforementioned pads PD may be electrically connected to the terminals of the terminal area PCB-P in the peripheral area PA.

For reference, since the display module 11 includes a substrate 100, it may also be stated that the substrate 100 has the display area DA and the peripheral area PA. Detailed descriptions of the substrate 100 are provided below.

Also, a plurality of transistors may be arranged in the display area DA. Among the plurality of transistors, depending on the type of transistor (N-type or P-type) and/or operating conditions, a first terminal of the transistor may be a source electrode or a drain electrode, and a second terminal may be an electrode different from the first terminal among the source electrode and the drain electrode. For example, when the first terminal is a source electrode, the second terminal may be a drain electrode.

In the following, an organic light-emitting display device will be described as an example of a display device according to an embodiment, but the display device of the present disclosure is not limited thereto. As an embodiment, the display device of the present disclosure may be an Inorganic Light Emitting Display or a display device such as a Quantum dot Light Emitting Display. For example, an emission layer included in the display device may include an organic material or an inorganic material. In some cases, the display device may include an emission layer and quantum dots located in the path of light emitted from the emission layer.

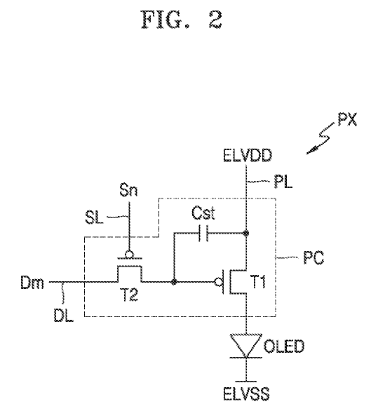

FIG. 2 is an example of a schematic equivalent circuit diagram of a subpixel of the display device of FIG. 1. The equivalent circuit diagram of FIG. 2 is a basic equivalent circuit diagram, and at least one of various modified equivalent circuit diagrams that apply the equivalent circuit diagram of FIG. 2 may be applied to a display module according to an embodiment.

For convenience of explanation, a pMOS-type thin film transistor is shown in FIG. 2, but the pixel circuit in this specification is not limited to the pMOS-type thin film transistor and may be variously modified.

As shown in FIG. 2, each subpixel PX may include a pixel circuit PC connected to a scan line SL and a data line DL, and a light-emitting element OLED connected to the pixel circuit PC.

For example, the pixel circuit PC may include a driving thin film transistor T1, a switching thin film transistor T2, and a storage capacitor Cst. The switching thin film transistor T2 is connected to the scan line SL and the data line DL, and may be configured to transmit a data signal Dm input through the data line DL to the driving thin film transistor T1 according to a scan signal Sn input through the scan line SL.

For example and without limitation, the driving thin film transistor T1 is a driving thin film transistor, and the switching thin film transistor T2 may be a thin film transistor for a switching operation.

For example and without limitation, the storage capacitor Cst is connected to the switching thin film transistor T2 and the driving voltage line PL, and may store a voltage corresponding to the difference between the voltage received from the switching thin film transistor T2 and the first power voltage(or driving voltage) ELVDD supplied to the driving voltage line PL.

For example and without limitation, the driving thin film transistor T1 is connected to the driving voltage line PL and the storage capacitor Cst, and may be configured to control a driving current flowing from the driving voltage line PL to the light-emitting element OLED in correspondence with the voltage value stored in the storage capacitor Cst. The light-emitting element OLED may emit light having a predetermined luminance according to the driving current.

The light-emitting element OLED may receive a second power voltage(or common voltage) ELVSS. For example, the light-emitting element OLED may receive the second power voltage or common voltage) ELVSS through a counter electrode (cathode), and the light-emitting element OLED may emit light having a predetermined luminance according to the driving current according to the voltage difference between the first power voltage(or driving voltage) ELVDD and the second power voltage(or common voltage) ELVSS.

In FIG. 2, a case where the pixel circuit PC includes two thin film transistors and one storage capacitor Cst is described, but the present disclosure is not limited to this configuration with two transistors and one capacitor. For example, the pixel circuit PC may include two or more capacitors, and/or three or more thin film transistors.

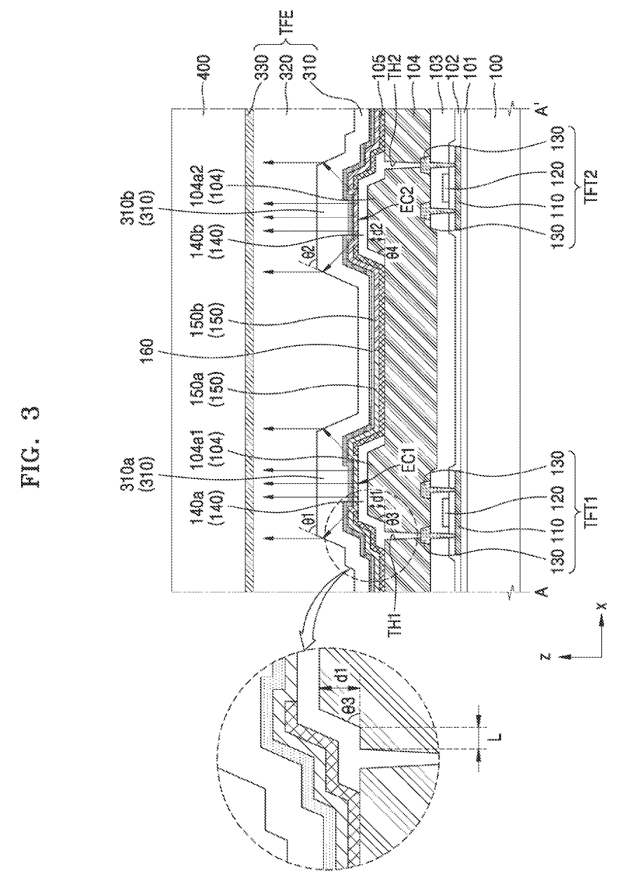

FIG. 3 is an example of a cross-sectional view schematically showing a cross-section obtained from the display area of FIG. 1 according to aspects of the present disclosure.

The substrate 100 may include areas corresponding to the display area DA and the peripheral area PA outside the display area DA, as described above. The substrate 100 may include various flexible or bendable materials.

For example, the substrate 100 may include glass, metal, or polymer resin. Additionally, the substrate 100 may include polymer resins such as polyethersulphone, polyacrylate, polyetherimide, polyethylene naphthalate, polyethylene terephthalate, polyphenylene sulfide, polyarylate, polyimide, polycarbonate, or cellulose acetate propionate.

For example, the substrate 100 may have a multilayer structure including two layers each containing such polymer resin and a barrier layer containing inorganic material (such as silicon oxide, silicon nitride, silicon oxynitride, etc.) between the two layers. Alternatively, the substrate 100 may include inorganic materials such as silicon oxide, silicon nitride, silicon oxynitride, etc., and various layers and components for screen display (for example, display elements using organic light emission, display elements using Liquid Crystal, etc.) may be disposed on the substrate 100 containing inorganic materials.

A buffer layer 101 may be located on the substrate 100. The buffer layer 101 may serve as a barrier layer and/or blocking layer to prevent the diffusion of impurity ions, prevent the penetration of moisture or external air, and planarize the surface of the substrate 100. The buffer layer 101 may include silicon oxide, silicon nitride, or silicon oxynitride. Additionally, the buffer layer 101 may control the rate of heat supply during the crystallization process for forming a semiconductor layer 110 so that the semiconductor layer 110 is uniformly crystallized.

The semiconductor layer 110 may be located on the buffer layer 101. The semiconductor layer 110 may be made of polysilicon and may include a channel region where impurities are not doped, and source and drain regions formed by doping impurities on both sides of the channel region. The impurities vary depending on the type of thin film transistor, and may be N-type impurities or P-type impurities.

A gate insulating film 102 may be located on the semiconductor layer 110. The gate insulating film 102 may be an element for ensuring insulation between the semiconductor layer 110 and a gate layer 120. The gate insulating film 102 may include inorganic materials such as silicon oxide, silicon nitride, and/or silicon oxynitride, and may be between the semiconductor layer 110 and the gate layer 120. Additionally, the gate insulating film 102 may be formed to correspond to the entire surface of the substrate 100, and may have a structure in which through-holes are formed in predetermined portions of the gate insulating film 102. Thus, insulating films containing inorganic materials may be formed through chemical vapor deposition (CVD) or atomic layer deposition (ALD). The formation of insulating films through CVD or ALD is also applicable to the embodiments and their modifications described below.

The gate layer 120 may be located on the gate insulating film 102. The gate layer 120 may be disposed in a position that vertically overlaps with the semiconductor layer 110, and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

An interlayer insulating film 103 may be located on the gate layer 120. The interlayer insulating film 103 may cover the gate layer 120. The interlayer insulating film 103 may be made of inorganic material. For example, the interlayer insulating film 103 may be a metal oxide or metal nitride, and specifically, the inorganic material may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZrO₂). The interlayer insulating film 103, in some embodiments, may be made of a dual structure of SiOx/SiNy or SiNx/SiOy.

Although not shown in FIG. 3, an additional gate layer and an additional interlayer insulating film may be between the gate layer 120 and a conductive layer 130, and may be applied to various embodiments. In this case, the additional gate layer may include the same material as the gate layer 120and may have the gate layer 120. The additional interlayer insulating film may include the same material as the interlayer insulating film 103, and the additional interlayer insulating film may have the same layer structure as the interlayer insulating film 103.

The conductive layer 130 may be located on the interlayer insulating film 103. The conductive layer 130 may serve as an electrode connected to the source/drain region of the semiconductor layer 110 through a through-hole in the interlayer insulating film 103. The conductive layer 130 may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the conductive layer 130 may include a Ti layer, an Al layer, and/or a Cu layer.

In this specification, the semiconductor layer 110, the gate layer 120, and the conductive layer 130 may constitute thin film transistors TFT1, TFT2. The thin film transistors TFT1, TFT2 may include, for convenience of explanation, a first thin film transistor TFT1 corresponding to one subpixel and a second thin film transistor TFT2 corresponding to another subpixel.

An organic insulating layer 104 may be located on the conductive layer 130. The organic insulating layer 104 may be an organic insulating layer that covers the upper portion of the conductive layer 130 and has a generally flat upper surface, serving as a planarization layer. The organic insulating layer 104 may include organic materials such as acryl, Benzocyclobutene (BCB), hexamethyldisiloxane (HMDSO), etc. The organic insulating layer 104 may have various modifications, such as being composed of a single layer or multiple layers.

Also, although not shown in FIG. 3, additional conductive layers and additional insulating layers may be between the conductive layer 130 and the pixel electrode, and may be applied to various embodiments. In this case, the additional conductive layer may include the same material as the conductive layer 130 and may have the same layer structure as the conductive layer 130. The additional insulating layer may include the same material as the organic insulating layer 104 and may have the same layer structure as the organic insulating layer 104.

For example, the organic insulating layer 104 may have a first through-hole TH1 and a second through-hole TH2. The first through-hole TH1 and the second through-hole TH2 may be formed through an etching process. For convenience of explanation, only two through-holes are shown in the drawing, but the organic insulating layer 104 may include additional through-holes. The first through-hole TH1 and the second through-hole TH2 may penetrate through the organic insulating layer 104 over the conductive layer 130 and allow a connection to the conductive layer 130.

The organic insulating layer 104 may include a first, first protrusion 104a1 having a first height d1 and a first, second protrusion 104a2 having a second height d2. The first, first protrusion 104a1 and the first, second protrusion 104a2 may protrude toward the upper portion with reference to the upper surface of the organic insulating layer 104. For convenience of explanation, only two protrusions are shown in the drawing, but the organic insulating layer 104 may include additional protrusions.

For example and without limitation, the first height d1 of the first, first protrusion 104a1 and the second height d2 of the first, second protrusion 104a2 may be in a range of 1 micrometer to 3 micrometers.

When the first height d1 of the first, first protrusion 104a1 is less than 1 micrometer, the step of the first pixel electrode 140a is too small, making the light refraction effect negligible, and when the first height (d1) of the first, first protrusion (104a1) exceeds 3 micrometers, the step of the first pixel electrode 140a is too large, which may cause the first pixel electrode 140a to be disconnected or the first intermediate layer 150a to be formed unevenly. The height requirements and effects on light refraction may also apply equally to the first, second protrusion 104a2 and the second pixel electrode 140b.

For example, the first height d1 of the first, first protrusion 104a1 may be in a range of 1.5 micrometers to 2 micrometers. Particularly in this range, the refraction effect for light of the first wavelength may be optimized, maximizing the light emission efficiency of the display module 11. The optimization of height for maximum light emission efficiency in the range of 1.5 to 2 micrometers may also apply equally to the first, second protrusion 104a2 and light of the second wavelength.

The first, first protrusion 104a1 and the first, second protrusion 104a2 may include the same material as the organic insulating layer 104. The first, first protrusion 104a1 and the first, second protrusion 104a2 may be formed simultaneously with the organic insulating layer 104 using halftone, or may be formed on the organic insulating layer 104 through a separate process.

The first, first protrusion 104a1 may be disposed around the first through-hole TH1. For example, the first, first protrusion 104a1 may be spaced apart from the first through-hole TH1 by a first distance L. The first distance L may be 1 micrometer or more.

The first, second protrusion 104a2 may be disposed around the second through-hole TH2. For example, the first, second protrusion 104a2 may be spaced apart from the second through-hole TH2 by a second distance. The second distance may be 1 micrometer or more.

The first, first protrusion 104a1 and the first, second protrusion 104a2 may be portions for forming steps for other layers or other components disposed on the first, first protrusion 104a1 and the first, second protrusion 104a2. Other layers or other components disposed on the first, first protrusion 104a1 and the first, second protrusion 104a2 may have steps corresponding to the first, first protrusion 104a1 and the first, second protrusion 104a2.

A pixel electrode 140 may be located on the organic insulating layer 104. The pixel electrode 140 may be connected to the conductive layer 130 through through-holes TH1, TH2 formed in the organic insulating layer 104. A display element may be located on the pixel electrode 140. An organic light-emitting diode may be used as the display element. That is, the organic light-emitting diode may be on the pixel electrode 140. The pixel electrode 140 may include a transparent conductive layer formed of a transparent conductive oxide such as ITO, In₂O₃, or IZO, and a reflective layer formed of a metal such as Al or Ag. For example, the pixel electrode 140 may have a three-layer structure of ITO/Ag/ITO.

The pixel electrode 140 may include a first pixel electrode 140a electrically connected to the first thin film transistor TFT1 through the first through-hole TH1, and a second pixel electrode 140b electrically connected to the second thin film transistor TFT2 through the second through-hole TH2.

The first pixel electrode 140a may have a step corresponding to the first, first protrusion 104a1. The first pixel electrode 140a may have a step corresponding to the first height d1. The first pixel electrode 140a may cover the upper surface of the organic insulating layer 104 around the first, first protrusion 104a1, the outer side surface of the first, first protrusion 104a1, and the upper surface of the first, first protrusion 104a1. The first pixel electrode 140a may be formed along the shape of the first, first protrusion 104a1. Since the first pixel electrode 140 is formed to cover the first, first protrusion 104a1, the first pixel electrode 140a may have a step corresponding to the first height d1 of the first, first protrusion 104a1. The thickness of the first, first protrusion 104a1 may be greater than the thickness of a pixel-defining layer 105, and the pixel-defining layer 105 may include an inorganic material so that the pixel-defining layer 105 is a thin pixel-defining layer

The second pixel electrode 140b may have a step corresponding to the first, second protrusion 104a2. The second pixel electrode 140b may have a step corresponding to the second height d2. The second pixel electrode 140b may cover the upper surface of the organic insulating layer 104 around the first, second protrusion 104a2, the outer side surface of the first, second protrusion 104a2, and the upper surface of the first, second protrusion 104a2. The second pixel electrode 140b may be formed along the shape of the first, second protrusion 104a2. Since the second pixel electrode 140b is formed to cover the first, second protrusion 104a2, the first pixel electrode 140a may have a step corresponding to the second height d2 of the first, second protrusion 104a2. The thickness of the first, second protrusion 104a2 may be greater than the thickness of the pixel-defining layer 105, and the pixel-defining layer 105 may include an inorganic material to implement a thin pixel-defining layer.

The pixel-defining layer 105 is located on the organic insulating layer 104 and may be arranged to cover the edge of the pixel electrode 140. That is, the pixel-defining layer 105 may cover the edge of the pixel electrode 140. The pixel-defining layer 105 has an opening corresponding to a pixel PX, and the opening may be formed so that at least the central portion of the pixel electrode 140 is exposed toward an upwards. Also, a spacer (not shown) may be disposed on the pixel-defining layer 105.

The pixel-defining layer 105 may include organic materials such as polyimide or HMDSO. Alternatively, the pixel-defining layer 105 may include an inorganic material, for example. For example, the pixel-defining layer 105 may include at least one inorganic material selected among silicon nitride, aluminum nitride, zirconium nitride, titanium nitride, hafnium nitride, tantalum nitride, silicon oxide, aluminum oxide, titanium oxide, tin oxide, and silicon oxynitride.

When the pixel-defining layer 105 includes an inorganic material, the thickness of the pixel-defining layer 105 may be less than the thickness of a pixel-defining layer 105 made of an organic material Therefore, when forming the pixel-defining layer 105 using an inorganic material, a relatively thin pixel-defining layer 105 may be formed.

The pixel-defining layer 105 may cover the edge of the pixel electrode 140. The pixel-defining layer 105 may expose at least the central portion of the pixel electrode 140 toward an upper portion. At least the central portion of the exposed pixel electrode 140 may be defined as an emission area.

For example, the pixel-defining layer 105 may cover the edge of the first pixel electrode 140a. The pixel-defining layer 105 may expose at least a central portion EC1 of the first pixel electrode 140a toward an upper portion.

For example, the pixel-defining layer 105 may cover the edge of the second pixel electrode 140b. The pixel-defining layer 105 may expose at least a central portion EC2 of the second pixel electrode 140b toward an upper portion.

An intermediate layer 150 and a counter electrode 160 may be located on the opening of the pixel-defining layer 105. The intermediate layer 150 includes a low molecular weight material or a high molecular weight material. When the intermediate layer 150 includes a low molecular weight material, the intermediate layer 150 may also include a Hole Injection Layer, a Hole Transport Layer, an Emission Layer, an Electron Transport Layer, and/or an Electron Injection Layer. When the intermediate layer 150 includes a high molecular weight material, the intermediate layer 150 may generally have a structure including a hole transport layer and an emission layer.

For example, the intermediate layer 150 may include a first intermediate layer 150a that generates light of a first wavelength and a second intermediate layer 150b that generates light of a second wavelength. Although not shown in the drawings, the intermediate layer 150 may further include a third intermediate layer (not shown) that generates light of a third wavelength. For example, the first wavelength may refer to a wavelength in a wavelength band of visible blue light, and the second wavelength may refer to a wavelength in a wavelength band of visible red light or a wavelength in a wavelength band of visible green light. For example, the first wavelength may be smaller or shorter than the second wavelength. The first intermediate layer 150a and the second intermediate layer 150b may be disposed on the same layer.

For example and without limitation, the first intermediate layer 150a disposed on the pixel-defining layer 105, generates light of the first wavelength, and may cover at least the central portion EC1 of the first pixel electrode 140a. The second intermediate layer 150b disposed on the pixel-defining layer 105, generates light of the second wavelength, and may cover at least the central portion EC2 of the second pixel electrode 140b.

For example, the first height d1 of the first, first protrusion 104a1 may correspond to the first wavelength, and the second height d2 of the first, second protrusion 104a2 may correspond to the second wavelength. For example and without limitation, when the first wavelength is less than the second wavelength, the first height d1 may be greater than the second height d2. Because the degree of refraction changes as the wavelength size changes, the height of the protrusion may be adjusted for optimized light refraction.

The counter electrode 160 may include a transparent conductive layer formed of transparent conductive oxide such as ITO, In₂O₃, or IZO. The pixel electrode 140 may be used as an anode, and the counter electrode 160 may be used as a cathode. Of course, the polarity of the electrodes may also be applied in the opposite way.

The structure of the intermediate layer 150 is not limited to the description above and may be other structures. For example, at least one of the layers constituting the intermediate layer 150 may be formed integrally with the counter electrode 160. As another embodiment, the intermediate layer 150 may include a patterned layer corresponding to each of a plurality of pixel electrodes 140.

For example, the counter electrode 160 is disposed on the upper portion of the display area DA and may be disposed on the entire surface of the display area DA. However, as described below, the counter electrode 160 in this specification may be distinguished to correspond to each of the emission areas.

The counter electrode 160 may be electrically coupled to a common power supply line (not shown) disposed in the peripheral area PA. In one embodiment, the counter electrode 160 may extend to a barrier wall (not shown). A thin film encapsulation layer TFE covers the entire display area DA and may be arranged to extend toward the peripheral area PA to cover at least a portion of the peripheral area PA.

The thin film encapsulation layer TFE may extend to the outside of the common power supply line (not shown). The thin film encapsulation layer TFE may include a first encapsulation layer 310, a second encapsulation layer 320, and a third encapsulation layer 330, and the second encapsulation layer 320 may be between the first encapsulation layer 310 and the third encapsulation layer 330.

For example, the first encapsulation layer 310 and the third encapsulation layer 330 may be inorganic encapsulation layers containing inorganic materials. The first encapsulation layer 310 and the third encapsulation layer 330 may include one or more inorganic materials such as aluminum oxide, titanium oxide, tantalum oxide, hafnium oxide, zinc oxide, silicon oxide, silicon nitride, or silicon oxynitride.

The first encapsulation layer 310 and the third encapsulation layer 330 may be a single layer or multiple layers including the aforementioned materials. The first encapsulation layer 310 and the third encapsulation layer 330 may include the same material or different materials. The thicknesses of the first encapsulation layer 310 and the third encapsulation layer 330 may be different from each other. The thickness of the first encapsulation layer 310 may be greater than the thickness of the third encapsulation layer 330. Alternatively, the thickness of the third encapsulation layer 330 may be greater than the thickness of the first encapsulation layer 310, or the thickness of the first encapsulation layer 310 and the third encapsulation layer 330 may be equal to each other.

For example, the second encapsulation layer 320 may be an organic encapsulation layer. The second encapsulation layer 320 may include a monomer-based material or a polymer-based material. The polymer-based material may include at least one of acrylic resin, epoxy resin, polyimide, and polyethylene. In one embodiment, the second encapsulation layer 320 may include acrylate.

For example, the first encapsulation layer 310 is disposed on the first intermediate layer 150a and may have a first refractive index. Alternatively, the first encapsulation layer 310 may include a material having a first refractive index. For example, when the first encapsulation layer 310 is SiOn, the first encapsulation layer 310 may have a refractive index of approximately 1.6 to 1.7.

The first encapsulation layer 310 may serve as a convex lens on the intermediate layer 150 covering at least the central portion of the pixel electrode 140. For the purpose of serving as a convex lens on the intermediate layer, the first encapsulation layer 310 may include protrusions that are convex toward the upper portion with respect to the upper surface of the first encapsulation layer 310. The protrusions of the first encapsulation layer 310 may include the same material as the first encapsulation layer 310.

For example, a second, first protrusion 310a may be convex upward beyond the upper surface of the first encapsulation layer 310. The second, first protrusion 310a may have an upper surface and an outer side surface. The upper surface and the outer side surface of the second, first protrusion 310a may be at a higher position (with reference to the substrate) than the upper surface of the surrounding first encapsulation layer 310. In a plan view, the first pixel electrode 140a may be disposed within the second, first protrusion 310a. In a plan view, at least the central portion EC1 of the first pixel electrode 140a may be disposed within the upper surface of the second, first protrusion 310a. In a plan view, at least the central portion EC1 of the first pixel electrode 140a may not overlap with the outer side surface of the second, first protrusion 310a.

The non-overlapping arrangement between the central portion EC1 of the first pixel electrode 140a and the outer side surface of the second, first protrusion 310a may be in consideration of the optical path of light of the first wavelength generated from the first intermediate layer 150a. For example, the second, first protrusion 310a may be disposed in the optical path of light of the first wavelength proceeding from the first intermediate layer 150 in a direction opposite to the substrate 100. Light of the first wavelength traveling in a direction perpendicular to the substrate 100 must pass through the upper surface of the second, first protrusion 310a, and may be guided not to be refracted as the light passes through the upper surface of the second, first protrusion 310a.

Also, the light having the first wavelength traveling in a direction not perpendicular to the substrate 100 may be guided to be refracted by passing through the outer side surface of the second, first protrusion 310a. For example, the outer side surface of the second, first protrusion 310a may refract light having the first wavelength in a direction approximately perpendicular to the substrate 100 (for example, in a direction toward an observer looking at the screen). As the light having the first wavelength passes through the outer side surface of the second, first protrusion 310a, light of the first wavelength traveling in a direction not perpendicular to the substrate may be refracted to proceed in a direction generally perpendicular to the substrate 100. As a result, the light emission efficiency may be increased.

The slope θ1 of the outer side surface of the second, first protrusion 310a may be different from the slope θ3 of the outer side surface of the first, first protrusion 104a1. For example, the slope θ1 of the outer side surface of the second, first protrusion 310a may be steeper than the slope θ3 of the outer side surface of the first, first protrusion 104a1. As a result, the effect of the second, first protrusion 310a as a convex lens may be enhanced.

For example, a second, second protrusion 310b may be convex upward beyond the upper surface of the first encapsulation layer 310. The second, second protrusion 310b may have an upper surface and an outer side surface. The upper surface and the outer side surface of the second, second protrusion 310b may be at a higher position (with reference to the substrate) than the upper surface of the surrounding first encapsulation layer 310. In a plan view, the second pixel electrode 140b may be disposed within the second, second protrusion 310b. In a plan view, at least the central portion EC2 of the second pixel electrode 140b may be disposed within the upper surface of the second, second protrusion 310b. In a plan view, at least the central portion EC2 of the second pixel electrode 140b may not overlap with the outer side surface of the second, second protrusion 310b.

The non-overlapping arrangement between the central portion EC2 of the second pixel electrode 140b and the outer side surface of the second, second protrusion 310b may be in consideration of the optical path of light of the second wavelength generated from the second intermediate layer 150b. For example, the second, second protrusion 310b may be disposed in the optical path of light of the second wavelength. Light of the second wavelength traveling in a direction perpendicular to the substrate 100 must pass through the upper surface of the second, second protrusion 310b, and may be guided not to be refracted as it passes through the upper surface of the second, second protrusion 310b.

Also, the light having the second wavelength traveling in a direction not perpendicular to the substrate may be guided to be refracted by passing through the outer side surface of the second, second protrusion 310b. For example, the outer side surface of the second, second protrusion 310b may refract light having the second wavelength in a direction approximately perpendicular to the substrate 100 (for example, in a direction toward an observer looking at the screen). As it passes through the outer side surface of the second, second protrusion 310b, light of the second wavelength traveling in a direction not perpendicular to the substrate may be refracted to proceed in a direction generally perpendicular to the substrate. As a result, the light emission efficiency may be increased.

The slope θ2 of the outer side surface of the second, second protrusion 310b may be different from the slope θ4 of the outer side surface of the first, second protrusion 104a2. For example, the slope θ2 of the outer side surface of the second, second protrusion 310b may be steeper than the slope θ4 of the outer side surface of the first, second protrusion 104a2. As a result, the effect of the second, second protrusion 310b as a convex lens may be enhanced.

To implement the same refraction phenomenon as a convex lens through the first encapsulation layer 310 and the second encapsulation layer 320, the difference between the first refractive index of the first encapsulation layer 310 and the second refractive index of the second encapsulation layer 320 may be in a range of 0.1 to 0.7 (provided that the first refractive index is greater than the second refractive index). For example and without limitation, when the second encapsulation layer 320 includes a monomer, the second refractive index is approximately 1.5. When the difference between the first refractive index and the second refractive index of the second encapsulation layer 320 is in a range of 0.1 to 0.7, the light efficiency increases by more than 10% compared to when the difference between the first refractive index and the second refractive index is not in this range.

For example, the height of the second, first protrusion 310a may correspond to the first wavelength, and the height of the second, second protrusion 310b may correspond to the second wavelength. For example, the first wavelength is less than the second wavelength, and the height of the second, first protrusion 310a may be greater than the height of the second, second protrusion 310b. Because the degree of refraction changes as the wavelength size changes, the height of a protrusion may be adjusted for optimized light refraction.

For example, the slope θ1 of the outer side surface of the second, first protrusion 310a may correspond to the first wavelength, and the slope θ2 of the outer side surface of the second, second protrusion 310b may correspond to the second wavelength. Here, the slope θ1 of the outer side surface of the second, first protrusion 310a may refer to the internal angle between the outer side surface of the second, first protrusion 310a and a reference plane, and the reference plane may refer to the substrate 100 or the upper surface of the second, first protrusion 310a. The slope θ2 of the outer side surface of the second, second protrusion 310b may refer to the internal angle between the outer side surface of the second, second protrusion 310b and a reference plane, and the reference plane may refer to the substrate or the upper surface of the second, second protrusion 310b.

For example, the first wavelength is less than the second wavelength, and the slope θ1 of the outer side surface of the second, first protrusion 310a may be steeper than the slope θ2 of the outer side surface of the second, second protrusion 310b. Because the degree of refraction changes as the wavelength size changes, the slope of the outer side surface of a protrusion may be adjusted for optimized light refraction.

A barrier wall (not shown) may be located on the peripheral area PA of the substrate 100. In one embodiment, the barrier wall (not shown) may include a three-layer structure including a portion of the organic insulating layer 104, a portion of the pixel-defining layer 105, and a portion of the spacer (not shown), but is not necessarily limited to the three-layer structure.

The barrier wall (not shown) is arranged to surround the display area DA and may prevent the material of the organic encapsulation layer 320 of the thin film encapsulation layer TFE from overflowing to the outside of the substrate 100. Therefore, the second encapsulation layer 320 may be in contact with the inner side surface of the barrier wall (not shown) facing the display area DA. Here, the statement that the organic encapsulation layer 320 is in contact with the inner side surface of the barrier wall (not shown) may be understood as the first encapsulation layer 310 being between the organic encapsulation layer 320 and the barrier wall (not shown), and the second encapsulation layer 320 contacts the first encapsulation layer 310.

The first encapsulation layer 310 and the third encapsulation layer 330 are disposed on the barrier wall (not shown) and may extend to the edge side of the substrate 100. However, depending on the case, the barrier wall (not shown) may include a plurality of barrier walls.

A functional layer 400 may be disposed on the third encapsulation layer 330. The functional layer 400 is shown as a single layer for convenience and may correspond to one or more layers such as a layer having a lower refractive index than the third encapsulation layer 330, a touch electrode layer, a color filter layer, a window member, etc.. When the functional layer is a low refractive layer, the low refractive layer may prevent refraction phenomena caused by the third encapsulation layer 330.

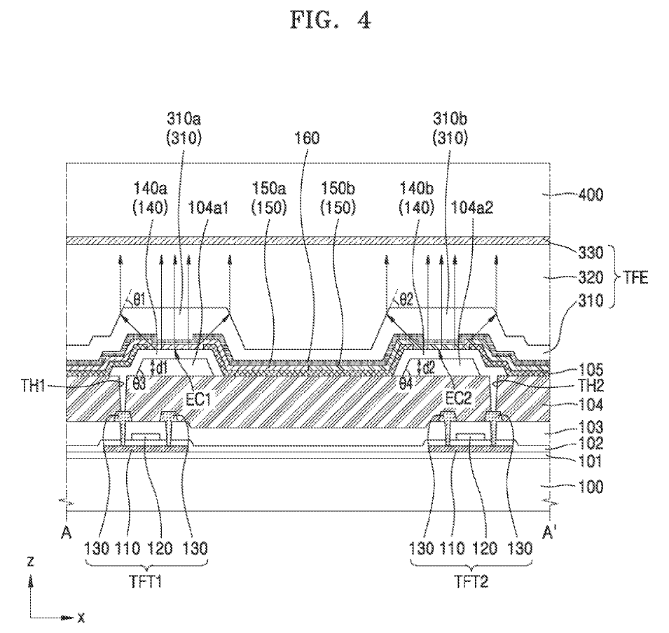

As shown in FIG. 3, the thickness of the first encapsulation layer 310 may vary by region. For example, the thickness of the region of the first encapsulation layer 310 that overlaps with the emission area (for example, an opening corresponding to a pixel PX formed in the pixel-defining layer 105 may be thicker than the thickness of other regions. The difference in thickness of the first encapsulation layer 310 by region helps light to be refracted toward the front of the screen (for example, in the z-axis direction). These features may also apply equally to FIGS. 4, 5, 6, and FIG. 12 described below.

FIG. 4 is an example of a cross-sectional view schematically showing a cross-section obtained from the display area of FIG. 1 according to aspects of the present disclosure. For reference, descriptions of FIG. 4 that are substantially the same as those provided above may be omitted.

As shown in FIG. 4, the first, first protrusion 104a1 and the first, second protrusion 104a2 may be disposed on the organic insulating layer 104. Unlike the illustration in FIG. 3, the first, first protrusion 104a1 and the first, second protrusion 104a2 may include materials different from the organic insulating layer 104 as separate components from the organic insulating layer 104.

For example, the first, first protrusion 104a1 and the first, second protrusion 104a2 may include conductive materials (for example, metal materials such as aluminum (Al), copper (Cu), titanium (Ti), etc.), and may be in direct contact with the first pixel electrode 140a and the second pixel electrode 140b. Therefore, the effect of reducing the resistance of each of the first pixel electrode 140a and the second pixel electrode 140b may occur.

As described above, since the first height d1 of the first, first protrusion 104a1 corresponds to the first wavelength and the second height d2 of the first, second protrusion 104a2 corresponds to the second wavelength, the first height d1 may be greater than the second height d2.

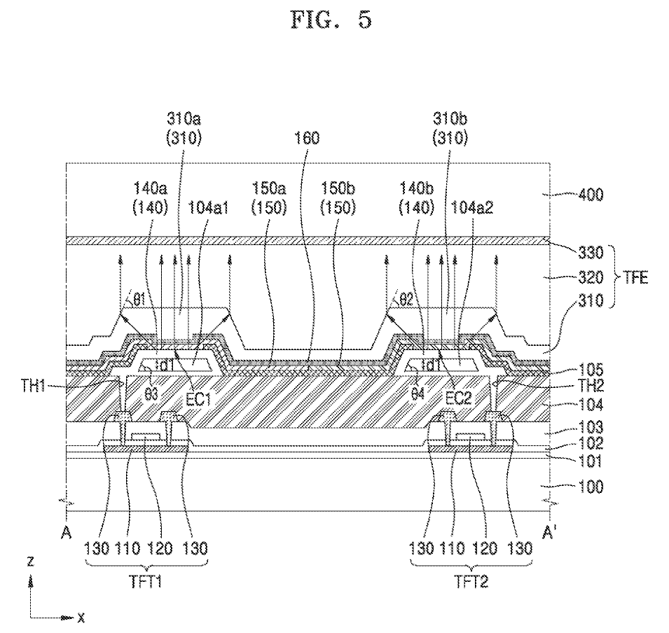

FIG. 5 is an example of a cross-sectional view schematically showing a cross-section obtained from the display area of FIG. . For reference, descriptions of FIG. 5 that are substantially the same as those provided above may be omitted.

As shown in FIG. 5, the first, first protrusion 104a1 may be disposed inside the first pixel electrode 140a, and the first, second protrusion 104a2 may be disposed inside the second pixel electrode 140b. The first, first protrusion 104a1 may be disposed inside the first pixel electrode 140a, and the first pixel electrode 140a may cover all of the bottom surface, upper surface, and outer side surface of the first, first protrusion 104a1. Therefore, the volume of the first pixel electrode 140a may be increased by the volume of the first, first protrusion 104a1, and the second, second protrusion 310a of the first encapsulation layer 310 may be convex or protruding toward the upper portion according to the enlarged first pixel electrode 140a.

As described above, since the first' height d1' of the first, first protrusion 104a1 corresponds to the first wavelength and the second' height d2' of the first, second protrusion (104a2) corresponds to the second wavelength, the first' height d1' may be greater than the second' height d2'. The first, first protrusion 104a1 and the first, second protrusion 104a2 of FIG. 5 may include organic materials and may be formed through a deposition process.

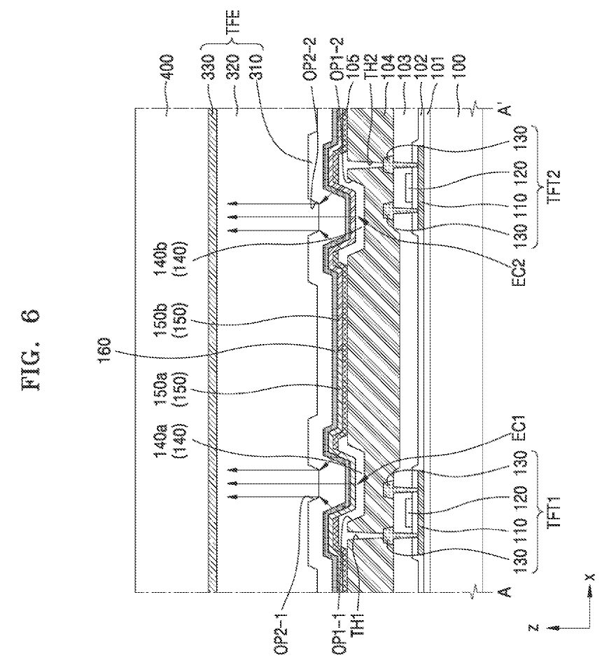

FIG. 6 is an example of a cross-sectional view schematically showing a cross-section obtained from the display area of FIG. 1 according to aspects of the present disclosure. For reference, descriptions of FIG. 6 that are substantially the same as those provided above may be omitted.

In an example of FIG. 6, the first refractive index of the first encapsulation layer 310 may be less than the second refractive index of the second encapsulation layer 320. As the first refractive index is less than the second refractive index, the protrusions of FIGS. 3 to 5 may be changed to openings in FIG. 6.

As shown in FIG. 6, the pixel-defining layer 105 may have a first, first groove OP1-1. The first, first groove OP1-1 is formed on the upper surface of the pixel-defining layer 105 and may have a shape that is recessed by a certain depth from the upper surface of the pixel-defining layer 105. The first, first groove OP1-1 of FIG. 6 may be a concept opposite to the first, first protrusion 104a1 described above.

The first pixel electrode 140a may be formed along the inner side surface of the first, first groove OP1-1 and the bottom surface of the first, first groove OP1-1. As a result, the shape of the first pixel electrode 140a in the cross-sectional view may correspond to the shape of the first, first groove OP1-1 in the cross-sectional view.

The first intermediate layer 150a may also be formed along the inner side surface and the bottom surface of the first, first groove OP1-1. As a result, the shape of the first intermediate layer 150a in the cross-sectional view may correspond to the shape of the first pixel electrode 140a in the cross-sectional view.

The counter electrode 160 may also be formed along the inner side surface and the bottom surface of the first, first groove OP1-1. As a result, the shape of the counter electrode 160 in the cross-sectional view may correspond to the shape of the first intermediate layer 150a in the cross-sectional view.

The first encapsulation layer 310 may be formed along the inner side surface and the bottom surface of the first, first groove OP1-1. As a result, the shape of the first intermediate layer 150a in the cross-sectional view may correspond to the shape of the counter electrode 160 in the cross-sectional view. The first encapsulation layer 310 may have a second, first groove OP2-1 of a smaller size than the first, first groove OP1-1. In a plan view, the second, first groove OP2-1 may be disposed inside the first, first groove OP1-1. The second, first groove OP2-1 is formed in the upper surface of the first encapsulation layer 310 and may refer to a groove recessed by a certain depth from the upper surface of the first encapsulation layer 310.

However, in this specification, when a groove is stated to be (relatively) small in size, it may mean that the area of the bottom surface of the groove and the area of the inner side surface of the groove are (relatively) smaller than the comparison target.

As shown in FIG. 6, the pixel-defining layer 105 may have a first, second groove OP1-2. The first, second groove OP1-2 is formed in the upper surface of the pixel-defining layer 105 and may have a shape that is recessed by a certain depth from the upper surface of the pixel-defining layer 105. The first, second groove OP1-2 of FIG. 6 may be a concept opposite to the first-2nd protrusion 104a2 described above.

The second pixel electrode 140b may be formed along the inner side surface and the bottom surface of the first, second groove OP1-2. As a result, the shape of the second pixel electrode 140b in the cross-sectional view may correspond to the shape of the first, second groove OP1-2 in the cross-sectional view.

The second intermediate layer 150b may also be formed along the inner side surface and the bottom surface of the first, second groove OP1-2. As a result, the shape of the second intermediate layer 150b in the cross-sectional view may correspond to the shape of the second pixel electrode 140b in the cross-sectional view.

The counter electrode 160 may also be formed along the inner side surface and the bottom surface of the first, second groove OP1-2. As a result, the shape of the counter electrode 160 in the cross-sectional view may correspond to the shape of the second intermediate layer 150b in the cross-sectional view.

The first encapsulation layer 310 may be formed along the inner side surface and the bottom surface of the first, second groove OP1-2. As a result, the shape of the first encapsulation layer 310 in the cross-sectional view may correspond to the shape of the counter electrode 160 in the cross-sectional view. The first encapsulation layer 310 may have a second, second groove OP2-2 of a smaller size (for example, a lower depth or a smaller area of the bottom surface) than the first, second groove OP1-2. In a plan view, the second, second groove OP2-2 may be disposed inside the first, second groove OP1-2. The second, second groove OP2-2 is formed in the upper surface of the first encapsulation layer 310 and may refer to a groove recessed by a certain depth from the upper surface of the first encapsulation layer 310.

The obtuse angle between the inner side surface of the second, first groove OP2-1 and the upper surface of the substrate (or the bottom surface of the second, first groove OP2-1) may be greater than the obtuse angle between the inner side surface of the first, first groove OP1-1 and the upper surface of the substrate (or the bottom surface of the first, first groove OP1-1). The larger obtuse angle between the inner side surface of the second, first groove and the substrate may be because the second, first groove (OP2-1) is formed after the first, first groove (OP1-1) is formed. Such a structure with a larger obtuse angle between the inner side surface of the second, first groove OP2-1 and the upper surface of the substrate (or the bottom surface of the second, first groove OP2-1) helps light to be refracted toward the front of the screen (for example, in the z-axis direction).

The obtuse angle between the inner side surface of the second, second groove OP2-2 and the upper surface of the substrate 100 (or the bottom surface of the second, second groove OP2-2) may be greater than the obtuse angle between the inner side surface of the first, second groove OP1-2 and the upper surface of the substrate 100 (or the bottom surface of the first, second groove OP1-2. The larger obtuse angle between the inner side surface of the second, second groove and the substrate 100 may be because the second, second groove OP2-2 is formed after the first-2nd groove OP1-2 is formed. Such a structure with a larger obtuse angle between the inner side surface of the second, second groove OP2-2 and the upper surface of the substrate (or the bottom surface of the second, second groove OP2-2) helps light to be refracted toward the front of the screen (for example, in the z-axis direction).

As a result of the first encapsulation layer 310 having the second, first groove OP2-1 and the second, second groove OP2-2 in the first intermediate layer 150a and the second intermediate layer 150b, the first encapsulation layer 310 may serve as a concave lens. Therefore, light having the first wavelength generated from the first intermediate layer 150a that converges toward the center may be refracted in a direction perpendicular to the substrate 100 due to the difference in refractive index between the first encapsulation layer 310 and the second encapsulation layer 320. Light of the second wavelength generated from the second intermediate layer 150b that converges toward the center may be refracted in a direction perpendicular to the substrate 100 due to the difference in refractive index between the first encapsulation layer 310 and the second encapsulation layer 320. As a result, the light emission efficiency of the display module 11 may be increased.

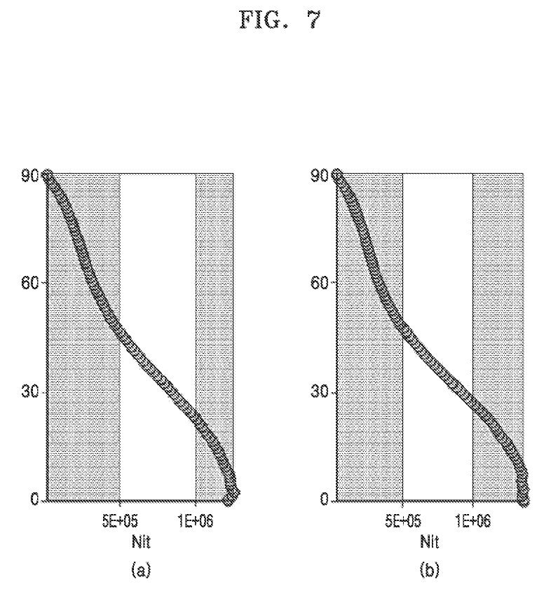

FIG. 7 is a diagram showing (a) a graph representing the light emission efficiency of a display module according to a comparative example and (b) a graph representing the light emission efficiency of a display module according to FIG. 3.

For reference, graphs (a) and (b) are luminance profiles for green light obtained through simulation. The y-axis of the graphs represents the viewing angle, ranging from 0 degrees to 90 degrees, and the x-axis represents the number of rays of measured green light, which can be understood as the luminance of light. A large number of rays can be understood to mean that the luminance of light is bright.

Graph (a) is a graph obtained based on conditions for a display module that does not use protrusions according to FIGS. 3 to 5 or grooves according to FIG. 6, and graph (b) is a graph obtained based on conditions for the display module of FIG. 3. All other conditions in the simulation, except for the inclusion of protrusions, are the same.

When displaying a screen close to a user's eyes, such as with a Virtual Reality (VR) device, the light emission efficiency at viewing angles from 0 degrees to 30 degrees is important. In terms of the luminance of light between viewing angles of 0 degrees and 30 degrees in both graphs, it is confirmed that the average luminance (number of rays) of graph (b) is greater than the average luminance (number of rays) of graph (a).

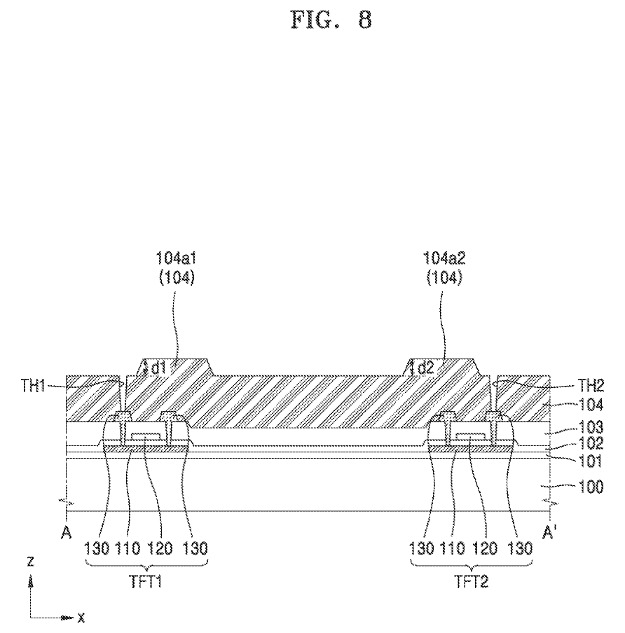

FIGS. 8 to 12 are diagrams sequentially showing a process of manufacturing the display module of FIG. 3 according to aspects of the present disclosure.

For reference, descriptions of FIGS. 8 to 12 that are substantially the same as those given above with reference to FIGS. 1 to 7 may be omitted.

A method of manufacturing a display module according to an aspects of the present disclosure (hereinafter, a method of manufacturing a display module) may include: forming a buffer layer 101 on a substrate 100, forming a semiconductor layer 110 on the buffer layer 101, forming a gate insulating film 102 on the semiconductor layer 110, forming a gate layer 130 on the gate insulating film 102, forming an interlayer insulating film 103 on the gate layer 120; forming through-holes in the interlayer insulating film 103 and the gate insulating film 102, forming a conductive layer 130 on the interlayer insulating film 103 and filling the formed through-holes with the conductive layer, forming an organic insulating layer 104 on the conductive layer 130, and forming a first through-hole TH1 and a second through-hole TH2 in the organic insulating layer 104. Here, the step of forming each layer may use conventionally known deposition methods, etc., and the step of forming through-holes may use conventionally known etching processes, etc. The first through-hole TH1 is disposed on the first thin film transistor TFT1, and the second through-hole TH2 may be disposed on the second thin film transistor TFT2.

As shown in FIG. 8, the method of manufacturing the display module may further include forming a first, first protrusion 104a1 and a first, second protrusion 104a2 on the organic insulating layer 104. For example, the step of forming the first, first protrusion 104a1 and the first, second protrusion 104a2 may be performed as a separate process from the step of forming the organic insulating layer 104. Alternatively, when a halftone process is used, the step of forming the first, first protrusion 104a1 and the first, second protrusion 104a2 may be the same process as the step of forming the organic insulating layer 104.

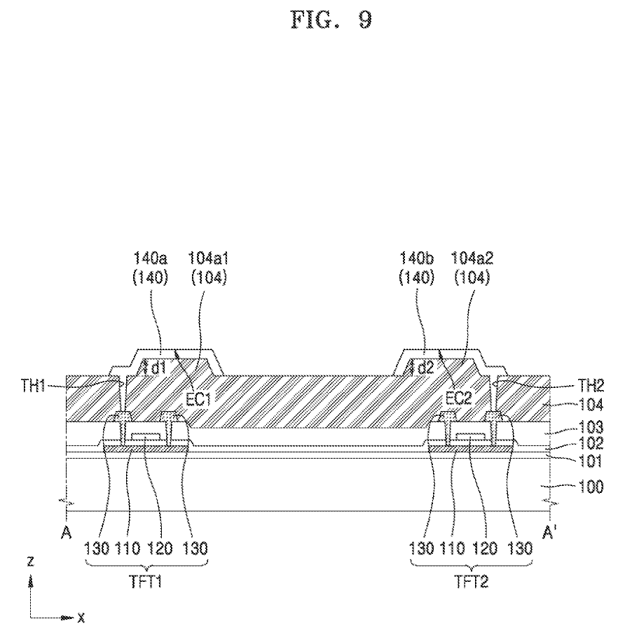

As shown in FIG. 9, the method of manufacturing the display module may further include forming a first pixel electrode 140a covering the first, first protrusion 104a1 and a second pixel electrode 140b covering the first, second protrusion 104a2. The first pixel electrode 140a is filled in the first through-hole TH1, and the second pixel electrode 140b may be filled in the second through-hole TH2.

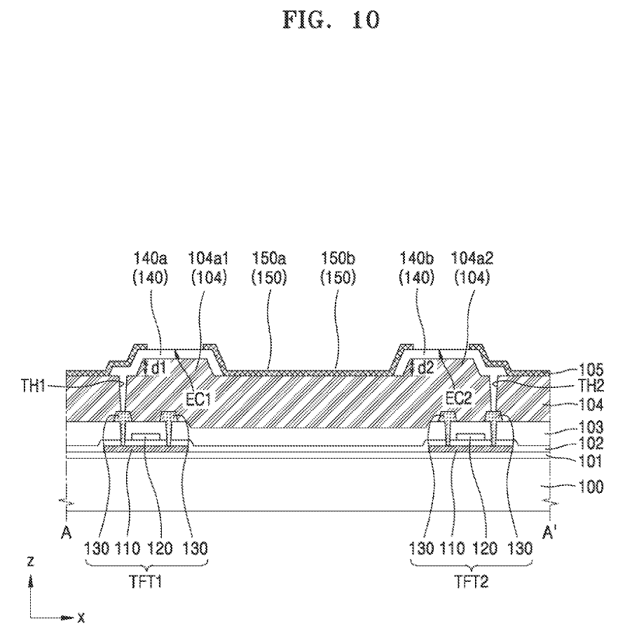

As shown in FIG. 10, the method of manufacturing the display module may further include forming a pixel-defining layer 105 that exposes at least a central portion EC1 of the first pixel electrode 140a toward an upper portion and exposes at least a central portion EC2 of the second pixel electrode 140b toward an upper portion. The pixel-defining layer 105 may cover the edge of the first pixel electrode 140a, the edge of the second pixel electrode 140b, and the upper surface of the organic insulating layer.

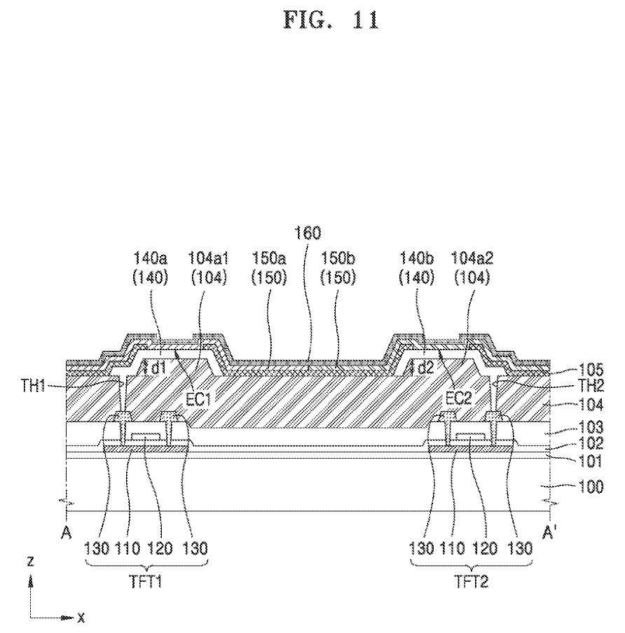

As shown in FIG. 11, the method of manufacturing the display module may further include forming a first intermediate layer 150a and a second intermediate layer 150b on the pixel-defining layer 105, at least the central portion EC1 of the first pixel electrode 140a, and at least the central portion EC2 of the second pixel electrode 140b. For example, the first intermediate layer 150a may be formed first and then the second intermediate layer 150b may be formed later, and the order in which the first intermediate layer 150a and the second intermediate layer 150b are formed may be changed as needed.

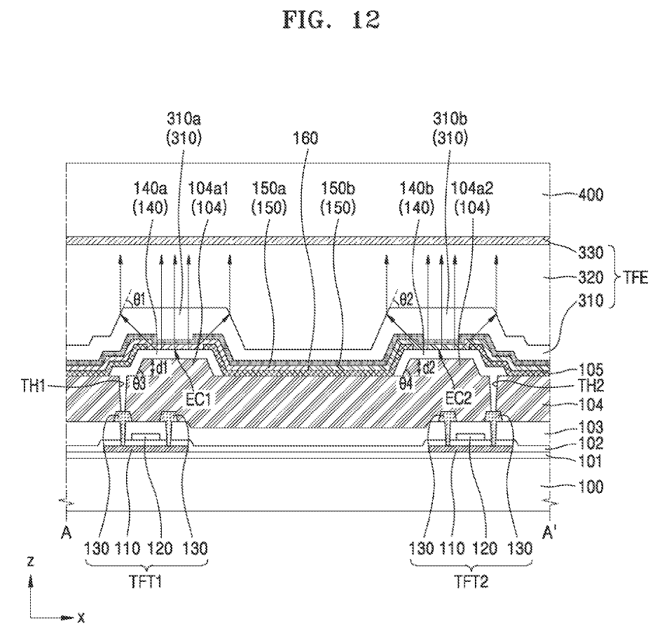

As shown in FIG. 12, the method of manufacturing the display module may further include forming a thin film encapsulation layer TFE on the first intermediate layer 150a and the second intermediate layer 150b. The thin film encapsulation layer TFE includes a first encapsulation layer 310, a second encapsulation layer 320, and a third encapsulation layer 330, and the first encapsulation layer 310, the second encapsulation layer 320, and the third encapsulation layer 330 may be formed in sequence.

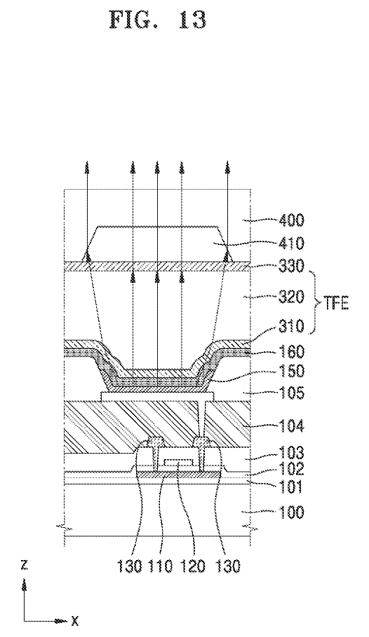

FIG. 13 is a cross-sectional view showing an example of a cross-section of a display module according to aspects of the present disclosure.

As shown in FIG. 13, the display module according to this implementation may separately include a high refractive layer 410 to concentrate light formed from the intermediate layer. The high refractive layer 410 is disposed on the thin film encapsulation layer TFE, and a functional layer 400 (for example, a low refractive layer) may be disposed on the high refractive layer 410.

However, since the high refractive layer 410 is disposed on the thin film encapsulation layer TFE, the distance between the high refractive layer 410 and the intermediate layer 150 is relatively far. The fact that there is a relatively large distance between the high refractive layer 410 and the intermediate layer 150 means that the light concentration capability is reduced.

The display module according to an embodiment has an advantage in that, unlike the comparative example, a separate high refractive layer 410 is not required. In the case of the comparative example, there is a problem that the light concentration efficiency is lowered because the distance between the high refractive layer 410 and the intermediate layer 150 is far. Specifically, as the thin film encapsulation layer TFE is interposed between the high refractive layer 410 and the intermediate layer 150, the distance increases by the thickness of the thin film encapsulation layer, causing a problem of light dispersion to that extent.

In contrast, according to the display module according to an embodiment, since direct light concentration is performed near the intermediate layer 150 through the second, first protrusion 310a and the second, second protrusion 310b or grooves OP4-1, OP4-2 formed in the first encapsulation layer 310, the optical efficiency is significantly improved.

In addition, the present disclosure has an advantage in that it can optimize the height and slope of the protrusion or opening for each wavelength, allowing independent control of the light emission efficiency of each RGB. The ability to optimize the height and slope of the protrusion or opening for each wavelength to independently control the light emission efficiency of each RGB is a feature that is difficult to implement with the high refractive layer structure of the comparative example.

Also, from a manufacturing process perspective, while the comparative example requires a separate high refractive layer formation process, the present disclosure can be implemented simply by adding protrusion or opening patterns in the existing organic insulating layer formation process, resulting in simplified processes and reduced manufacturing costs.

Hereinafter, based on the above contents, an electronic device according to a preferred embodiment will be described in detail as follows.

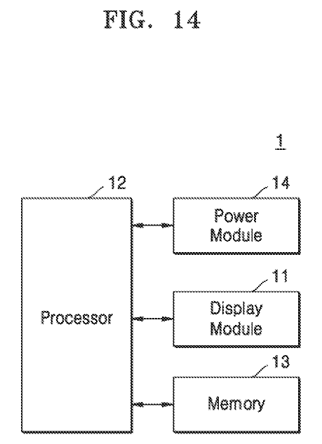

FIG. 14 is a block diagram of an electronic device according to an embodiment.

Referring to FIG. 14, an electronic device 1 according to an embodiment may include a display module 11, one or more processors 12, a memory 13, and a power module 14.

The one or more processors 12 may include at least one selected from a group including a central processing unit (CPU), an application processor (AP), a graphic processing unit (GPU), a communication processor (CP), an image signal processor (ISP), and a controller. The one or more processors may perform operation individually or as collective with each processor performing a part of the operation. The one or more processors may include one or more processor cores, specialized compute units (such as Single Instruction Multiple Data Units (SIMD), Nueral Processors, or Compression/Decompression (Codec) unit), etc.

The memory 15 may store data information necessary for the operation of the one or more processors 12 or the display module 11. When the one or more processors 12 executes an application stored in the memory 15, video data signals and/or input control signals are transmitted to the display module 11, and the display module 11 processes the provided signals to output video information through the display screen.

The power module 14 may include a power supply module such as a power adapter or a battery device, and a power conversion module that converts power supplied by the power supply module to generate power necessary for the operation of the electronic device 1.

At least one of the components of the electronic device 1 described above may be included in the display device according to the embodiments described above. Also, some of the individual modules included in one module functionally may be included in the display device, and other portions may be provided separately from the display device. For example, the display device may include a display module 11, and the one or more processors 12. The memory 13, and the power module 14 may be provided in the form of other devices within the electronic device 1 that are not the display device.

The display module 11 in FIG. 14 may refer to one of the examples of the display module 11 described in FIGS. 1 to 12. For convenience of explanation, other explanations are omitted, but those skilled in the art can easily and clearly understand the display module 11 of FIG. 14 based on the description of FIGS. 1 to 12.

In one embodiment, the electronic device 1 may include a memory 13 that stores data information, a processor 12 that generates data signals and/or control signals based on the data information, and a display module 11 that operates based on the data signals and/or control signals. The display module 11 may be any one of the display modules of FIGS. 1 to 12.

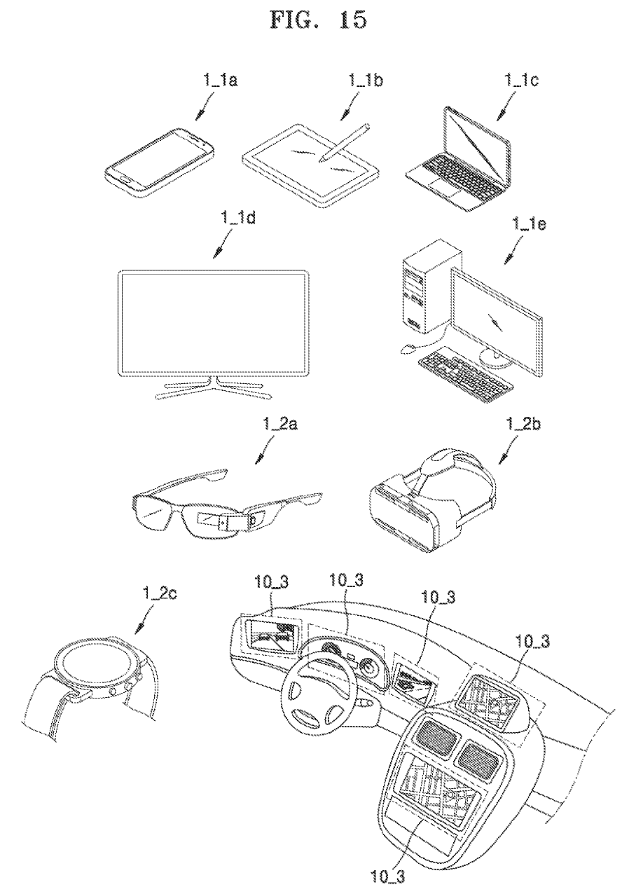

FIG. 15 is a schematic diagram of electronic devices according to various embodiments.

Referring to FIG. 15, various electronic devices to which the display device according to the embodiments is applied may include not only image display electronic devices such as a smartphone 10_1a, a tablet PC 10_1b, a laptop 10_1c, a TV 10_1d, a desktop monitor 10_1e, but also wearable electronic devices including display modules such as smart glasses 10_2a, a head mounted display 10_2b, a smart watch 10_2c, and vehicle electronic devices 10_3 including display modules such as an instrument panel of a car, a center fascia, a Center Information Display (CID) disposed on a dashboard, a room mirror display, etc.

As described above, the present disclosure has been described with reference to the embodiments shown in the drawings, but this is merely exemplary, and those skilled in the art will understand that various modifications and other equivalent embodiments are possible therefrom. Therefore, the true technical protection scope of the present disclosure should be determined by the technical spirit of the appended claims.

According to the one or more embodiments as described above, a display module with improved light emission efficiency and an electronic device including the same can be implemented. However, the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display module comprising:
a substrate;
a first thin film transistor disposed on the substrate;
an insulating layer disposed on the first thin film transistor and having a first through-hole, the insulating layer including a first, first protrusion having a first height around the first through-hole;
a first pixel electrode disposed on the insulating layer and electrically connected to the first thin film transistor through the first through-hole, the first pixel electrode having a step corresponding to the first height with reference to an upper surface of the insulating layer;
a pixel-defining layer disposed on the first pixel electrode and exposing at least a central portion of the first pixel electrode toward an upper portion;
a first intermediate layer disposed on the pixel-defining layer, generating light of a first wavelength, and covering at least the central portion of the first pixel electrode;
a first encapsulation layer disposed on the first intermediate layer, having a first refractive index, and including a second, first protrusion protruding toward the upper portion; and
a second encapsulation layer disposed on the first encapsulation layer and having a second refractive index that is less than the first refractive index.

2. The display module of claim 1, wherein,
in a plan view, the first, first protrusion is disposed within the second, first protrusion.

3. The display module of claim 1, wherein,
in a plan view, the first through-hole is spaced apart from the first, first protrusion.

4. The display module of claim 1, wherein,
in a plan view, the first pixel electrode is disposed within the second, first protrusion.

5. The display module of claim 1, wherein,
in a plan view, at least the central portion of the first pixel electrode is disposed within an upper surface of the second, first protrusion.

6. The display module of claim 5, wherein,
in a plan view, at least the central portion of the first pixel electrode does not overlap with an outer side surface of the second, first protrusion.

7. The display module of claim 1, wherein
a difference between the first refractive index and the second refractive index may be between 0.1 and 0.7 inclusive of endpoints.

8. The display module of claim 1, wherein
a thickness of the first, first protrusion is greater than a thickness of the pixel-defining layer.

9. The display module of claim 1, wherein the pixel defining layer includes an inorganic material, the first encapsulation layer includes an inorganic material, the second encapsulation layer includes a monomer-based material and
the display module further includes a third encapsulation layer disposed on the second encapsulation layer, wherein the third encapsulation layer includes an inorganic material.

10. The display module of claim 1, wherein
the second, first protrusion is disposed in an optical path of the light of the first wavelength proceeding from the first intermediate layer in a direction opposite to the substrate.

11. The display module of claim 1, wherein
an outer side surface of the second, first protrusion refracts the light of the first wavelength.

12. The display module of claim 1, wherein
the insulating layer has a second contact hole and includes a first, second protrusion having a second height around the second through-hole.

13. The display module of claim 12, further comprising:
a second thin film transistor disposed on the substrate;
a second pixel electrode disposed on a same layer as the first pixel electrode, electrically connected to the second thin film transistor through the second through-hole, having a step corresponding to the second height with reference to the upper surface of the insulating layer, and having at least a central portion exposed toward the upper portion by the pixel-defining layer; and
a second intermediate layer disposed on a same layer as the first intermediate layer, generating light of a second wavelength, and covering at least the central portion of the second pixel electrode.

14. The display module of claim 13, wherein
the first wavelength is less than the second wavelength, and the first height is greater than the second height.

15. The display module of claim 13, wherein
the first encapsulation layer further includes a second, second protrusion protruding toward the upper portion.

16. The display module of claim 15, wherein,
in a plan view, the first, second protrusion is disposed within the second, second protrusion.

17. The display module of claim 15, wherein,
in a plan view, the second through-hole is spaced apart from the first, second protrusion.

18. The display module of claim 15, wherein,
in a plan view, at least the central portion of the second pixel electrode is disposed within an upper surface of the second, second protrusion.

19. The display module of claim 15, wherein,
in a plan view, at least the central portion of the second pixel electrode does not overlap with an outer side surface of the second, second protrusion.

20. An electronic device comprising:
a memory configured to store data information;
one or more processors coupled to the memory and configured to generate a data signal and/or a control signal based on the data information, either individually or collectively; and
the display module configured to operate based on the data signal and/or the control signal, wherein the display module includes:
a substrate;
a first thin film transistor disposed on the substrate;
an insulating layer disposed on the first thin film transistor and having a first through-hole, the insulating layer including a first, first protrusion having a first height around the first through-hole;
a first pixel electrode disposed on the insulating layer and electrically connected to the first thin film transistor through the first through-hole, the first pixel electrode having a step corresponding to the first height with reference to an upper surface of the insulating layer;
a pixel-defining layer disposed on the first pixel electrode and exposing at least a central portion of the first pixel electrode toward an upper portion;
a first intermediate layer disposed on the pixel-defining layer, generating light of a first wavelength, and covering at least the central portion of the first pixel electrode;
a first encapsulation layer disposed on the first intermediate layer, having a first refractive index, and including a second, first protrusion protruding toward the upper portion; and
a second encapsulation layer disposed on the first encapsulation layer and having a second refractive index that is less than the first refractive index.
